(19) United States
(12) Patent Application Publication
(10) Pub. No.: US 2026/0076116 A1
(43) Pub. Date: Mar. 12, 2026

(54) DIFFUSION SUPPRESSION IN HIGH-TEMPERATURE ANNEALING OF NITRIDES

(71) Applicant: The Government of the United States of America, as represented by the Secretary of the Navy, Arlington, VA (US)

(72) Inventors: Alan G. Jacobs, Rockville, MD (US); Boris N. Feigelson, Springfield, VA (US)

(73) Assignee: The Government of the United States of America, as represented by the Secretary of the Navy, Arlington, VA (US)

(21) Appl. No.: 19/324,589

(22) Filed: Sep. 10, 2025

Related U.S. Application Data
(60) Provisional application No. 63/693,236, filed on Sep. 11, 2024.

(51) Int. Cl. H01L 21/223; H01L 21/02; H01L 21/324

(52) U.S. Cl. CPC H10P 32/12; H10P 14/3416; H10P 32/174; H10P 95/904

(57) ABSTRACT

A nitride semiconductor and method of making the same are provided. In embodiments, a method for manufacturing a nitride semiconductor includes: providing a nitride semiconductor material including at least one main dopant defining a p-type portion; doping the nitride semiconductor material with at least one co-dopant co-located with the main dopant, wherein the co-dopant reduces gas-enhanced diffusion of the main dopant by a component in an ambient gas during annealing; and annealing the nitride semiconductor material under pressure, thereby producing an annealed nitride semiconductor material with an activated main dopant. In implementations, a nitride semiconductor is produced including an annealed nitride semiconductor material doped with magnesium (Mg) and oxygen (O) in an activated p-type portion, wherein the Mg and O are present at a ratio of 2:1.

### CROSS-REFERENCE TO RELATED APPLICATIONS

This Application is a Nonprovisional of, and claims the benefit of priority under 35 U.S.C. § 119 based on, U.S. Provisional Patent Application No. 63/693236 filed September 11, 2024. The Provisional Application and all references cited herein are hereby incorporated by reference into the present disclosure in their entirety.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; nrltechtran@us.navy.mil, referencing Navy Case No. 211738-US03.

### BACKGROUND OF THE INVENTION

Aspects of the present invention relate generally to semiconductor manufacturing and, more particularly, to a method of suppressing diffusion of dopants into a nitride semiconductor during annealing.

Ion implanted dopant activation is a key enabling technique for high voltage, high power, and high frequency gallium nitride (GaN) electronics. Annealing or “activation annealing” is necessary after ion implantation to remove damage from the implantation process and to activate one or more dopants by moving the dopant atoms into the GaN lattice. This proves difficult for GaN as the material is metastable at high temperatures and ambient pressure, which may result in the GaN decomposing into metallic gallium and nitrogen gas.

In order to anneal GaN at high temperatures, one method uses higher than atmospheric pressure nitrogen gas within an annealing furnace to stabilize the solid phase and preclude or reduce decomposition of the solid. During such high-pressure annealing, which often occurs at 10-2000 Megapascals (MPa) in pressure, the GaN is heated at high pressure in a nitrogen atmosphere, however, this atmosphere can include minor contaminants such as oxygen, water, hydrogen, and other gasses. During activation annealing of GaN, often occurring from 1200-1500 degrees Celsius (°C) for minutes to hours, hydrogen in the gas phase can diffuse into the surface of the GaN, which can drastically affect the diffusivity of the dopant species. For example, when magnesium (utilized as a dopant to achieve p-type GaN) is implanted only a few hundred nanometers deep, activation annealing may cause the magnesium to diffuse multiple microns into the GaN material.

Significant (increased) diffusion of dopants proves deleterious as this makes control of the final semiconductor structure difficult. Moreover, such unintended diffusion of dopants may move shallow junctions and may spread out high concentrations of dopants, precluding some device designs. Furthermore, high surface concentrations of dopants greatly enhance ohmic contact formation in some final semiconductor devices. Since enhanced ohmic contact formation is often a necessary function, unintentional diffusion of dopants must be controlled to enable the fabrication of devices with such a function.

Furthermore, hydrogen passivates p-type doping of GaN by magnesium (whether incorporated by growth or implanted) such that hydrogen must be removed before magnesium-doped GaN will produce free holes for device operation. The diffusion of hydrogen and magnesium deep into GaN is problematic because the deeper the hydrogen diffuses into the GaN, the more difficult it is to remove for device fabrication.

One potential solution to hydrogen contamination of GaN is to remove the hydrogen from the initial atmosphere of an annealing furnace/chamber; however, this proves difficult for several reasons. First, hydrogen is present in annealing feed gasses and concentrated at annealing conditions. As an annealing atmosphere’s pressure increases, any minor component of the source gas is also pressurized. For example, a 1 part-per-million concentration of hydrogen in nitrogen gas (which is common in ultra-high purity nitrogen feed gas), at 1000 MPa annealing conditions, will have a 1 kPa vapor pressure in the chamber or ~1% of atmospheric pressure. This vapor pressure of hydrogen is significant and introduces a large source of hydrogen to diffuse into the GaN. Furthermore, such conditions produce a large volume of hydrogen that must be removed, even for higher purity feed gasses. While nitrogen sources are often filtered and purified to reduce contaminants to a level of ~1 part per billion (ppb), this still results in approximately 1 Pascal (Pa) of hydrogen vapor pressure, which acts as a detrimental hydrogen source.

Second, hydrogen is often generated in the anneal chamber of an annealing furnace. Any water present in the chamber or in the ambient annealing gas will react with heating elements of the furnace. Often these heating elements are made of carbon or metals which react with the water at high temperatures to steal the oxygen and produce free hydrogen. This means that even if the feed gas is perfectly pure, any water adsorbed onto surfaces of the chamber will produce hydrogen in-situ. This is often unavoidable.

Third, additional sources of hydrogen can include outgassing from a steel pressure vessel of an annealing furnace, sealing materials or gaskets of the annealing furnace, and other leaks from the outside world into the high-pressure chamber of the furnace during furnace loading or operating processes. Accordingly, there exists a need for methods to reduce hydrogen during the annealing of semiconductor materials, including nitride semiconductors.

### SUMMARY OF THE INVENTION

In a first aspect of the invention, there is method for manufacturing a nitride semiconductor including: providing a nitride semiconductor material including at least one main dopant defining a p-type portion; doping the nitride semiconductor material with at least one co-dopant co-located with the main dopant, wherein the co-dopant reduces gas-enhanced diffusion of the main dopant by a component in an ambient gas during annealing; and annealing the nitride semiconductor material under pressure, thereby producing an annealed nitride semiconductor material with an activated main dopant. In embodiments, the component that causes enhanced diffusion of the main dopant is hydrogen, wherein the co-dopant reduces the enhanced diffusion. In implementations, nitride is selected from the group consisting of: gallium nitride (GaN), aluminum nitride (AlN), indium nitride (InN), scandium nitride (ScN), yttrium nitride (YN), boron nitride (BN), alloys thereof, and combinations thereof. The main dopant may be selected from magnesium (Mg) and beryllium (Be). In implementations, the co-dopant is selected from the group consisting of silicon (Si), germanium (Ge), oxygen (O), sulfur (S), selenium (Se), transition metals, and combinations thereof. In embodiments, the co-dopant comprises a transition metal selected from the group consisting of yttrium (Y), scandium (Sc), and titanium (Ti). In certain embodiments, the main dopant is magnesium (Mg), the co-dopant is oxygen (O), and the Mg binds with O in the p-type portion of the nitride semiconductor material, thereby preventing hydrogen (H) from enhancing diffusion of the Mg through the nitrogen semiconductor material during the annealing.

In implementations of the invention, the annealing is performed at a temperature in the range of 1200-1500 degrees Celsius. In some implementations, the annealing is performed at temperature in the range of 1500-2200 degrees Celsius. The pressure may be between 0.1 and 5000 Megapascals (MPa). In aspects of the invention, the main dopant and the at least one co-dopant are present at a ratio of 2:1. In embodiments, the nitride semiconductor material has a thickness less than 200 microns. In implementations, the nitride semiconductor material has a thickness between 0.01 and 10 microns. This method may further include implanting one or more secondary dopants at an n-type portion of the nitride semiconductor material. In some implementations, the secondary dopant includes silicon (Si). The method may also include growing the nitride semiconductor layer on a substrate.

In another aspect of the invention, there is a nitride semiconductor including: an annealed nitride semiconductor material doped in an activated p-type portion with a main dopant selected from magnesium (Mg) and beryllium (Be), and a secondary dopant of oxygen (O), wherein the main dopant and O are present at a ratio of 2:1. In implementations, the nitride semiconductor includes a secondary dopant within a n-type portion of the nitride semiconductor material. The secondary dopant may be silicon (Si). The nitride semiconductor may also include a substrate directly supporting the annealed nitride semiconductor material. The nitride may be gallium nitride (GaN), aluminum nitride (AlN), indium nitride (InN), scandium nitride (ScN), yttrium nitride (YN), boron nitride (BN), alloys thereof, or combinations thereof.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1 shows a flowchart of an exemplary method in accordance with aspects of the present invention.

FIG. 2 is a cross-sectional side view of a multilayered nitride semiconductor in accordance with embodiments of the invention.

### DETAILED DESCRIPTION

Aspects of the present invention relate generally to semiconductor manufacturing and, more particularly, to a method of suppressing excess/accelerated diffusion of dopants into a nitride semiconductor during annealing. In implementations, a nitride semiconductor material (e.g., gallium nitride) with at least one main dopant (e.g., magnesium or beryllium) incorporated therein is implanted with a co-dopant (co-doping species) that reduces the effect of hydrogen gas on diffusivity of the main dopant(s) during annealing. The co-doped nitride semiconductor is then annealed under pressure in a nitrogen gas environment, which results in an annealed nitride semiconductor layer with an activated main portion (e.g., p-type portion).

In implementations, the co-doping species associates with the main dopant(s) in a way that reduces the effects of hydrogen on the diffusivity of the associated co-doping species/ main dopant(s). In some embodiments, the co-doping species associates with unwanted hydrogen, thereby precluding the hydrogen from enhancing diffusion of the main dopant(s).

In the specific case of gallium nitride (GaN) where enhanced diffusion of magnesium is sought to be suppressed, the co-doping species may comprise one or more donors, such as silicon or oxygen, one or more acceptors such as beryllium, or one or more transition metals such as yttrium, scandium, titanium, or others. Such co-doping species may require concentrations above the magnesium locally, at a specific ratio to the magnesium, or at a low concentration depending on the co-doping species. In one example, the magnesium to co-dopant ratio is 2:1.

Advantageously, embodiments of the invention maintain an implanted dopant profile, enabling effective device performance that is currently impossible utilizing standard annealing conditions. Moreover, using co-implanted species to control diffusion in accordance with embodiments of the invention provides an in-situ control mechanism without the need to utilize high-temperature getter material in a hot zone. Further, no changes or restrictions to device design and construction are necessary with co-implantation according to implementations of the invention.

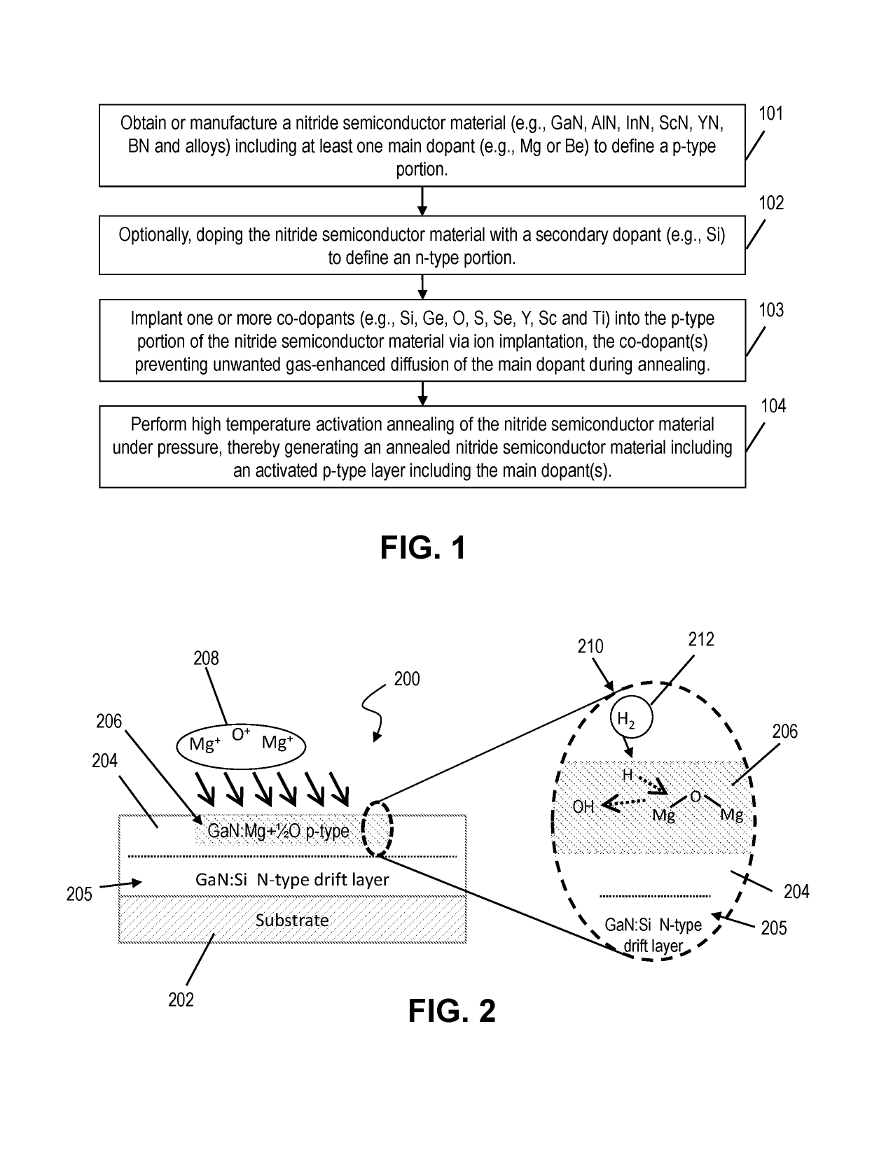

FIG. 1 shows a flowchart of an exemplary method in accordance with aspects of the present invention.

At 101, a nitride semiconductor material is provided or manufacturing, which includes at least one main dopant (inactivated) incorporated therein via implantation or during growth of the nitride semiconductor material to define a p-type portion or doping profile. In general, the term doping profile as used herein refers to a distribution and concentration of dopant impurities within a semiconductor material.

In implementations, the nitride semiconductor material is grown or adhered to another semiconductor layer or substrate material. In embodiments, the nitride semiconductor material is selected from: gallium nitride (GaN), aluminum nitride (AlN), indium nitride (InN), scandium nitride (ScN), yttrium nitride (YN), boron nitride (BN), and alloys thereof or combinations of the same. The main dopant may comprise a p-type dopant. In implementations, a main dopant is magnesium (Mg). In the case where the nitride semiconductor material is AlN, the main dopant may be beryllium (Be).

In instances of the invention, the nitride semiconductor material has a thickness of between 10 nm and 200 microns. In other instances of the invention, the nitride semiconductor material has a thickness between 10 nm and 10 microns. Manufacturing of the nitride semiconductor material may comprise growing the nitride semiconductor material on a substrate. Existing manufacturing methods may be utilized to manufacturing the doped nitride semiconductor material, and the present invention is not intended to be limited to particular manufacturing methods.

Optionally, at 102, the nitride semiconductor material is doped with a secondary dopant (e.g., Si) to define an n-type portion or doping profile (e.g., drift layer) of the nitride semiconductor material, which is different from the p-type portion. In implementations, the n-type portion is adjacent an interface with a substrate, and the p-type portion is between the n-type portion and a top surface of the nitride semiconductor material. See, for example, the p-type portion 206 and the n-type portion 205 adjacent the substrate 202 in FIG. 2.

At 103, one or more co-dopants are implanted into the nitride semiconductor material within the p-type portion via ion implantation, wherein the one or more co-dopants reduce the effect of an unwanted ambient gas on diffusivity of the main dopant(s) during activation annealing. This may be accomplished by reducing the diffusivity of the main dopant(s) directly, and/or by reducing the diffusivity of the unwanted ambient gas, thus preventing the unwanted ambient gas from enhancing diffusion of the main dopant(s) during activation annealing. In implementations, the co-dopant is selected from: silicon (Si), germanium (Ge), oxygen (O), sulfur (S), selenium (Se), beryllium (Be), transition metals including yttrium (Y), scandium (Sc), and titanium (Ti), and combinations of the same. In implementations, step 103 occurs at the same time that the main dopant(s) is implanted into the nitride semiconductor material at step 102.

In embodiments, the co-dopant(s) is ion implanted at a low energy to produce a shallow dopant implant, at energies to produce a doping profile matching the doping profile of the main dopant(s) (e.g., Mg). In embodiments, the unwanted ambient gas is hydrogen. In instances of the invention, the main dopant(s) and the co-dopant(s) are present in the nitride semiconductor material at a ratio of 2:1.

At 104, high-temperature activation annealing of the nitride semiconductor material is performed, resulting in an annealed nitride semiconductor material including activated main dopant(s). The annealing of step 104 may comprise multiple heating and cooling steps. In implementations, in order to activate ion-implanted co-dopant(s), damage to the nitride semiconductor material caused by the ion implantation must be removed, and the implanted ions must be moved from their as-implanted random positions within the material to desired lattice sites within the material. This requires a high annealing temperature relative to the material melting point of the nitride semiconductor material. In embodiments, the annealing temperature is greater or equal to 1200 °C. In the case of GaN, for example, the annealing temperature required is approximately 1200-1500°C. Other nitrides that would benefit from this relatively high annealing temperature include AlN, InN, ScN, YN, BN, and alloys or combinations of the same. In implementations, the activation annealing is conducted at a temperature in the range of 1500-2200 °C. This range may be utilized in conjunction with AlN, ScN and YN nitride semiconductor materials, for example. Such annealing temperatures require relatively high pressures to allow for dopant activation. In implementation, the activation annealing is performed in a furnace chamber having a pressure between 0.1 and 5000 MPa. In embodiments, the activation annealing is performed in a low hydrogen environment, where the hydrogen (H₂)vapor pressure (P) is greater than 1 x 10⁻⁶ bar. In implementations, the annealing is performed in a furnace including a gas feed of purified nitrogen gas (N₂), without any additional feed gasses.

### Experimental Results

In one experiment, GaN samples were doped with magnesium (Mg) as a main dopant. The concentration profile of an oxygen (O) co-dopant was matched to a ratio of the magnesium main dopant, and a portion of the GaN samples were implanted with the O co-dopant at a concentration approximately two times (2x) lower than the Mg concentration. After annealing at a temperature of 1300 °C for 60 minutes at the high pressure of 380 MPa in a nitrogen gas (N₂) atmosphere, samples implanted with only Mg showed marked diffusion of the Mg from a starting profile of ~300 nm to 1500 nm, while samples implanted with co-doped with Mg and O showed reduced Mg diffusion from the starting profile of ~300 nm to less than 1000 nm. Furthermore, the profile near the surface was minimally perturbed from the as-implanted profile, and the O itself retained the starting box profile after annealing and did not diffuse further through the GaN samples.

FIG. 2 is a cross-sectional side view of a multilayered nitride semiconductor 200 in accordance with embodiments of the invention. In embodiments, the multilayers nitride semiconductor 200 of FIG. 2 is manufactured using the method of FIG. 1.

The multilayered nitride semiconductor 200 of FIG. 2 includes a substrate 202 supporting a nitride semiconductor layer 204 in the form of GaN. The nitride semiconductor layer 204 includes a lower portion adjacent the substrate 202 doped with Si, creating an n-type drift layer indicated at 205. The nitride semiconductor layer 204 also includes an upper portion adjacent the upper surface of the GaN layer 204, which is doped with two dopants 208, comprising a main dopant Mg and a co-dopant O at a ratio of 2:1, creating a p-type portion 206.

A magnified view of the interface of the p-type portion 206 and the n-type portion 205 is illustrated at 210, and depicts an unwanted gas (H₂) 212. In implementations, Mg and O elements will bond within the GaN layer 204. During annealing of the multilayered nitride semiconductor 200, hydrogen elements (H) that make their way into the GaN layer 204 will be blocked from diffusing downward towards the n-type drift layer 205 by the bonded Mg and O elements, and will themselves bond with available O elements to generate hydroxyl groups (OH). These chemical reactions negate the effects of hydrogen on the diffusion of Mg during the annealing process (i.e., blocks hydrogen-enhanced diffusion of Mg). In this example, Mg and O are present at a concentration ratio of 2:1. Advantageously, the presence of Mg:O at the 2:1 ratio also increases hole concentrations (thermal activation efficiency) within the GaN layer 204.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the embodiments described. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for manufacturing a nitride semiconductor comprising:
providing a nitride semiconductor material including at least one main dopant defining a p-type portion;
doping the nitride semiconductor material with at least one co-dopant co-located with the main dopant, wherein the co-dopant reduces gas-enhanced diffusion of the main dopant by a component in an ambient gas during annealing; and
annealing the nitride semiconductor material under pressure, thereby producing an annealed nitride semiconductor material with an activated main dopant.

2. The method of claim 1, wherein the component in the ambient gas is hydrogen.

3. The method of claim 1, wherein the nitride is selected from the group consisting of: gallium nitride (GaN), aluminum nitride (AlN), indium nitride (InN), scandium nitride (ScN), yttrium nitride (YN), boron nitride (BN), alloys thereof, and combinations thereof.

4. The method of claim 1, wherein the at least one main dopant is selected from the group consisting of magnesium (Mg) and beryllium (Be).

5. The method of claim 1, wherein the at least one co-dopant is selected from the group consisting of silicon (Si), germanium (Ge), oxygen (O), sulfur (S), selenium (Se), transition metals, and combinations thereof.

6. The method of claim 5, wherein the at least one co-dopant comprises a transition metal selected from the group consisting of yttrium (Y), scandium (Sc), and titanium (Ti).

7. The method of claim 1, wherein the at least one main dopant is magnesium (Mg), the at least one co-dopant is oxygen (O), and the Mg binds with O in the p-type portion of the nitride semiconductor material, thereby preventing hydrogen (H) from enhancing diffusion of the Mg through the nitrogen semiconductor material during the annealing.

8. The method of claim 1, wherein the annealing is performed at a temperature in the range of 1200-1500 degrees Celsius.

9. The method of claim 1, wherein the annealing is performed at temperature in the range of 1500-2200 degrees Celsius.

10. The method of claim 1, wherein the pressure is between 0.1 and 5000 Megapascals (MPa).

11. The method of claim 1, wherein the at least one main dopant and the at least one co-dopant are present at a ratio of 2:1

12. The method of claim 1, wherein the nitride semiconductor material has a thickness less than 200 microns.

13. The method of claim 1, wherein the nitride semiconductor material has a thickness between 0.01 and 10 microns.

14. The method of claim 1, further comprising implanting one or more secondary dopants at an n-type portion of the nitride semiconductor material.

15. The method of claim 14, wherein the one or more secondary dopants comprises silicon (Si).

16. The method of claim 1, further comprising growing the nitride semiconductor layer on a substrate.

17. A nitride semiconductor comprising:
an annealed nitride semiconductor material doped in an activated p-type portion with a main dopant selected from magnesium (Mg) and beryllium (Be), and a secondary dopant of oxygen (O), wherein the main dopant and O are present at a ratio of 2:1.

18. The nitride semiconductor of claim 17, further comprising a secondary dopant within a n-type portion of the nitride semiconductor material.

19. The nitride semiconductor of claim 18, wherein the secondary dopant is silicon (Si).

20. The nitride semiconductor of claim 19, further comprising a substrate directly supporting the annealed nitride semiconductor material.
